(19) United States
(12) Patent Application Publication
(10) Pub. No.: US 2024/0183030 A1
(43) Pub. Date: Jun. 6, 2024

(54) SUBSTRATE TREATMENT APPARATUS USING SUPERCRITICAL FLUID

(71) Applicant: SEMES CO., LTD., Cheonan-si (KR)

(72) Inventors: Hae Won CHOI, Cheonan-si (KR); Thomas Jongwan KWON, Cheonan-si (KR); Chengyeh HSU, Busan (KR)

(73) Assignee: SEMES CO., LTD., Cheonan-si (KR)

(21) Appl. No.: 18/492,149

(22) Filed: Oct. 23, 2023

(30) Foreign Application Priority Data
Dec. 5, 2022 (KR) 10-2022-0167368

(51) Int. Cl. C23C 16/04; C23C 16/06

(52) U.S. Cl. CPC C23C 16/045; C23C 16/06

(57) ABSTRACT

Provided is a substrate treatment apparatus using a supercritical fluid, the apparatus capable of depositing a conformal film in a trench with a high aspect ratio and capable of performing void-free complete gap-filling. The substrate treatment apparatus includes: an upper vessel including a first body and a supply port formed in the first body and supplying a process fluid; a baffle plate installed in the upper vessel and supplying the process fluid supplied through the supply port to a treatment space by diffusing the process fluid; a lower vessel including a second body and an exhaust port formed in the second body and exhausting the process fluid from the treatment space; and a support plate installed in the lower vessel to face the baffle plate and supporting a substrate, wherein while a supercritical process is performed in the treatment space, the support plate is heated so that the temperature of the support plate is higher than that of the first body.

This application claims the benefit of Korean Patent Application No. 10-2022-0167368, filed on Dec. 5, 2022, in the Korean Intellectual Property Office, the disclosure of which is incorporated herein in its entirety by reference.

### BACKGROUND

### 1. Field

The present disclosure relates to a substrate treatment apparatus using a supercritical fluid.

### 2. Description of the Related Art

As semiconductor devices become increasingly highly integrated, individual circuit patterns are becoming more miniaturized to implement more semiconductor devices in the same area. That is, as the degree of integration of semiconductor devices increases, design rules for components of the semiconductor devices are being reduced.

In highly-scaled semiconductor devices, a trench filling process is becoming increasingly difficult. When a trench is filled with a metal through atomic layer deposition (ALD) or chemical vapor deposition (CVD), the trench with a high aspect ratio may not be sufficiently filled, and a seam or void or a pinch-off defect may occur inside the trench.

### SUMMARY

Aspects of the present disclosure provide a substrate treatment apparatus using a supercritical fluid, the apparatus capable of depositing a conformal film in a trench with a high aspect ratio and capable of performing void-free complete gap-filling.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a substrate treatment apparatus including: an upper vessel including a first body and a supply port formed in the first body and supplying a process fluid; a baffle plate installed in the upper vessel and supplying the process fluid supplied through the supply port to a treatment space by diffusing the process fluid; a lower vessel including a second body and an exhaust port formed in the second body and exhausting the process fluid from the treatment space; and a support plate installed in the lower vessel to face the baffle plate and supporting a substrate, wherein while a supercritical process is performed in the treatment space, the support plate is heated so that the temperature of the support plate is higher than that of the first body.

According to another aspect of the present disclosure, there is provided a substrate treatment apparatus comprising: vessels providing a treatment space for treating a substrate and comprising an upper vessel and a lower vessel detachably coupled so that the upper vessel and the lower vessel can be switched between a closed position for closing the treatment space and an open position for opening the treatment space; a support installed on a lower surface of the upper vessel and configured to support the substrate in the open position of the vessels; a hot plate installed in the lower vessel and heating a lower surface of the substrate in the closed position of the vessels; and a liner installed on at least a portion of an inner wall of the treatment space and made of a heat insulating material.

According to still another aspect of the present disclosure, there is provided a substrate treatment apparatus comprising: an upper vessel which comprises a first body comprising a center region and a peripheral region, a supply port formed in the center region and supplying a process fluid, and a first accommodating space connected to the supply port in the center region and recessed inward from the peripheral region; a baffle plate installed in the first accommodating space and supplying the process fluid supplied through the supply port to a treatment space by diffusing the process fluid; a lower vessel comprising a second body, an exhaust port formed in the second body and exhausting the process fluid from the treatment space, and a recessed second accommodating space; a hot plate installed in the second accommodating space to face the baffle plate; a first heat insulating liner installed on a lower surface of the baffle plate; a second heat insulating liner installed on a lower surface of the peripheral region of the first body; and a third heat insulating liner installed on sidewalls of the second accommodating space which surround side surfaces of the hot plate, wherein while a supercritical process is performed in the treatment space, the hot plate is heated so that the temperature of the hot plate is higher than those of the first body and the second body.

### BRIEF DESCRIPTION OF THE DRAWINGS

These and/or other aspects will become apparent and more readily appreciated from the following description of the embodiments, taken in conjunction with the accompanying drawings in which:

FIGS. 1 and 2 illustrate a substrate treatment apparatus according to an embodiment of the present disclosure;

FIG. 3 illustrates a substrate treatment apparatus according to an embodiment of the present disclosure;

FIG. 4 illustrates a substrate treatment apparatus according to an embodiment of the present disclosure;

FIG. 5 illustrates a substrate treatment apparatus according to an embodiment of the present disclosure;

FIG. 6 is a diagram for explaining a process fluid supply unit of a substrate treatment apparatus according to embodiments of the present disclosure;

FIG. 7 is an embodiment of FIG. 6;

FIG. 8 is a diagram for explaining the operation of a substrate treatment apparatus according to embodiments of the present disclosure;

FIG. 9 is a diagram for explaining a process of filling a trench with a metal using a substrate treatment method according to embodiments of the present disclosure; and

FIG. 10 illustrates a system to which a substrate treatment apparatus according to embodiments of the present disclosure is applied.

### DETAILED DESCRIPTION

Hereinafter, exemplary embodiments of the present disclosure will be described in greater detail with reference to the attached drawings. Advantages and features of the present disclosure and methods of accomplishing the same may be understood more readily by reference to the following detailed description of exemplary embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the invention to those skilled in the art, and the present disclosure will only be defined by the appended claims. Like reference numerals refer to like elements throughout the specification.

Spatially relative terms, such as “below,” “beneath,” “lower,” “above,” “upper” and the like, may be used herein for ease of description to describe the relationship of one element or component to another element(s) or component(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” or “beneath” can encompass both an orientation of above and below. The device may be otherwise oriented and the spatially relative descriptors used herein interpreted accordingly.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of the present disclosure.

Hereinafter, embodiments of the present disclosure will be described in detail with reference to the attached drawings. In the following description with reference to the attached drawings, like or corresponding elements will be indicated by like reference numerals, and a redundant description thereof will be omitted.

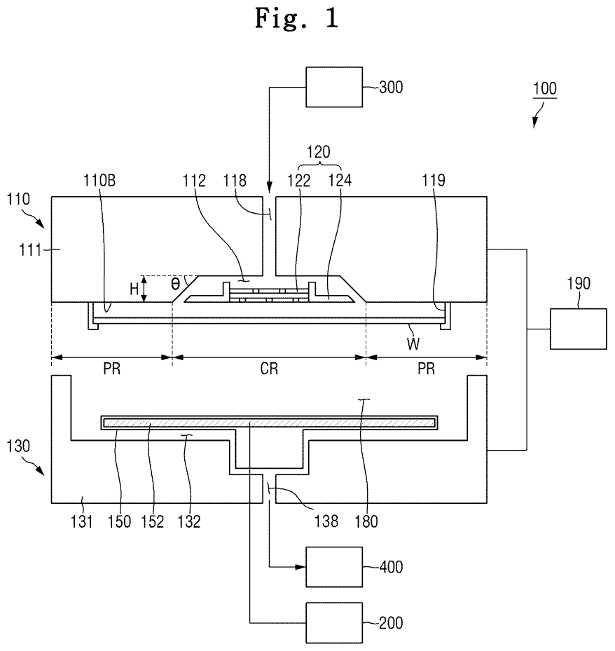

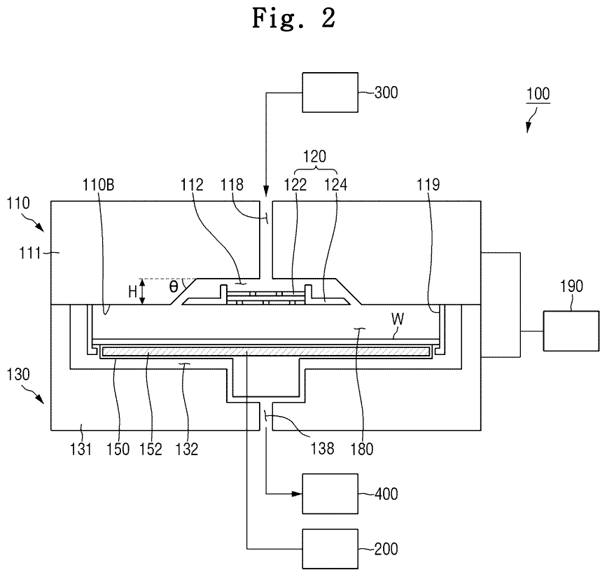

FIGS. 1 and 2 illustrate a substrate treatment apparatus according to an embodiment of the present disclosure. FIG. 1 illustrates a state in which a treatment space is open (i.e., an open position), and FIG. 2 illustrates a state in which the treatment space is closed (i.e., a closed position). The substrate treatment apparatus according to the embodiment of the present disclosure may be applied to a process (e.g., a deposition process) using a supercritical fluid.

Referring to FIGS. 1 and 2, the substrate treatment apparatus according to the embodiment of the present disclosure includes a reactor 100, a driving unit 190, a temperature control unit 200, a process fluid supply unit 300, and an exhaust unit 400. A controller (not illustrated) controls the operations of the reactor 100, the driving unit 190, the temperature control unit 200, the process fluid supply unit 300, and the exhaust unit 400. A program (software) for controlling these operations may be included in the controller (not illustrated).

The reactor 100 is a space for performing a process for a supercritical fluid.

A supercritical fluid is a substance at a temperature and pressure above its critical point and has the diffusivity of a gas and the solubility of a liquid. The supercritical fluid may be, but is not limited to, carbon dioxide (CO₂), water (H₂O), methane (CH₄), ethane (C₂H₆), propane (C₃H₈), ethylene (C₂H₄), propylene (C₃H₆), methanol (CH₃OH), ethanol (C₂H₅OH), or acetone (C₃H₆O). Carbon dioxide will be described below as an example of the supercritical fluid.

The reactor 100 includes an upper vessel 110, a support 119, a baffle plate 120, a lower vessel 130, and a support plate (or hot plate) 150.

The vessels 110 and 130 provide a treatment space 180 for treating a substrate W. The vessels 110 and 130 include the upper vessel 110 and the lower vessel 130 and are detachably coupled. Specifically, the upper vessel 110 and the lower vessel 130 can be switched between an open position (see FIG. 1) for opening the treatment space 180 and a closed position (see FIG. 2) for closing the treatment space 180 by the driving unit 190. The driving unit 190 determines relative positions by moving at least one of the upper vessel 110 and the lower vessel 130.

The upper vessel 110 includes a first body 111, a supply port 118, and a first accommodating space 112.

The first body 111 serves as the body of the upper vessel 110 and has the supply port 118 and the first accommodating space 112 formed therein. The first body 111 is made of a heat transferable material, for example, may be stainless steel (SUS).

The first body 111 includes a center region CR and a peripheral region PR surrounding the center region CR. The supply port 118 and the first accommodating space 112 are formed in the center region CR. The peripheral region PR may protrude toward the treatment space 180 from the center region CR. The support 119 may be installed in the peripheral area PR.

The supply port 118 may be installed to pass through the first body 111. The supply port 118 receives a process fluid from the process fluid supply unit 300 and delivers the received process fluid to the first accommodating space 112. As will be described later, the process fluid is a fluid for performing a supercritical process in the treatment space 180. The process fluid may be, for example, a first process fluid including a metal precursor and a supercritical fluid (i.e., the metal precursor dissolved by the supercritical fluid) or may be a second process fluid including a reducing fluid and a supercritical fluid (i.e., the reducing fluid dissolved by the supercritical fluid). However, the present disclosure is not limited thereto. Through the supply port 118, the first process fluid and the second process fluid may be alternately and repeatedly supplied a plurality of times, or the first process fluid and the second process fluid may be simultaneously supplied.

For example, the metal precursor of the first process fluid may be in the form of ML (where M is a metal, and L is a ligand), and the metal M may include Ru, Mo, Cu, TiN, TaN, Al, Ti, Ta, Ni, Nb, Rh, Pd, Ir, Ag, Au, Zn, or V, but the present disclosure is not limited thereto. The ligand L may consist of only C and/or H. However, the present disclosure is not limited thereto. That is, the ligand L may also consist of only one of Cₓ, H_{y}, and CₓH_{y} (where x and y are natural numbers).

The reducing fluid of the second process fluid may include, but is not limited to, oxygen (O₂), hydrogen (H₂), or ammonia (NH₃).

The first accommodating space 112 may be formed on a lower surface (or bottom surface) 110B of the first body 111. As illustrated, the first accommodating space 112 may be recessed inward from the lower surface 110B of the first body 111 (or recessed inward from the peripheral region PR). A depth H of the first accommodating space 112 may be, for example, 10 mm or more.

Side surfaces of the first accommodating space 112 may be inclined. That is, side and upper surfaces of the first accommodating space 112 may form an angle θ smaller than 90 degrees. The angle θ may be, for example, 10 to 70 degrees.

The baffle plate 120 is installed in the first accommodating space 112. The baffle plate 120 supplies a process fluid received through the supply port 118 to the treatment space 180 by diffusing the process fluid.

The baffle plate 120 includes a base 124 and perforated plates 122. The perforated plates 122 may be fixed by the base 124 and may be, for example, stacked in two or more layers. Perforated positions of a perforated plate 122 may be different from perforated positions of a perforated plate 122 installed directly on the above perforated plate 122. That is, when viewed in a vertical direction, the perforated positions of the lower perforated plate 122 are not aligned in a line with the perforated positions of the upper perforated plate 122 installed directly on the lower perforated plate 122. Since the perforated positions are not aligned in a line, a process fluid is sufficiently mixed through the first accommodating space 112 and the baffle plate 120 and then supplied to the substrate W.

The support 119 is installed on the lower surface 110B of the upper vessel 110 (i.e., a lower surface of the peripheral region PR). The support 119 is configured to support the substrate W when the vessels 110 and 130 are in the open position (when the upper vessel 110 and the lower vessel 130 are spaced apart from each other).

The lower vessel 130 includes a second body 131, an exhaust port 138, and a second accommodating space 132.

The second body 131 serves as the body of the lower vessel 130 and has the exhaust port 138 and the second accommodating space 132 formed therein. The second body 131 is made of a heat transferable material, for example, may be stainless steel (SUS).

The exhaust port 138 may be installed to pass through the second body 131. The exhaust port 138 exhausts a process fluid received from the treatment space 180 to the outside. The exhaust operation may be controlled by the operation of the exhaust unit 400 connected to the exhaust port 138.

The second accommodating space 132 may be installed on an upper surface of the second body 131. As illustrated, the second accommodating space 132 may be recessed inward from the upper surface of the second body 131.

The support plate 150 is installed in the lower vessel 130 to face the baffle plate 120. Specifically, the support plate 150 is installed in the second accommodating space 132. When the vessels 110 and 130 change from the open position to the closed position (i.e., in a state where the upper vessel 110 and the lower vessel 130 are in contact with each other), the substrate W may be transferred from the support 119 to the support plate 150 and then may be supported by the support plate 150. However, the present disclosure is not limited thereto. That is, even when the vessels 110 and 130 are in the closed position, the substrate W may be supported by the support 119. When the vessels 110 and 130 are in the closed position, the support plate 150 faces a lower surface of the substrate W.

A heat source 152 is installed inside the support plate 150. The heat source 152 may be, for example, a heater or a pipe through which a high-temperature fluid flows. When the heat source 152 is a heater, the temperature control unit 200 controls the temperature by supplying power to the heater. When the heat source 152 is a pipe, the temperature control unit 200 controls the temperature by supplying a high-temperature fluid to the pipe.

While a supercritical process is performed in the treatment space 180, the support plate 150 is heated by the heat source 152. Accordingly, the temperature of the substrate W rises. The temperature of the support plate 150 is controlled to be higher than that of the first body 111. Alternatively, the temperature of the support plate 150 may be controlled to be higher than that of the second body 131. That is, the support plate 150 becomes a hot plate, and other portions (i.e., the first body 111 and the second body 131) become cold walls.

While the supercritical process is performed in the treatment space 180, the temperature of the support plate 150 is controlled to be higher than those of the vessels 110 and 130. For example, while the supercritical process is performed in the treatment space 180, the support plate 150 may be at 150 to 350° C., and the upper vessel 110 and/or the lower vessel 130 may be at 35 to below 150° C.

When the vessels 110 and 130 are in the closed position to perform a supercritical process, a process fluid is supplied to the treatment space 180 to enter a supercritical state. Here, the support plate 150 is heated to increase the temperature of the substrate W. As the temperature of the substrate W increases, the supercritical process is intensively performed on the substrate W.

Since the upper vessel 110 and the lower vessel 130 are made of a heat transferable material such as SUS, they are easy to heat, but difficult to insulate. When the upper vessel 110 and the lower vessel 130 are heated, the temperature of the treatment space 180 rises, thereby increasing the efficiency of the supercritical process in the treatment space 180. However, devices outside and around the upper vessel 110 and the lower vessel 130 are inevitably affected by the high temperature.

Therefore, in the substrate treatment apparatus according to the embodiment of the present disclosure, the support plate 150 is heated to 150° C. or higher, but the upper vessel 110 and the lower vessel 130 are maintained at a relatively lower temperature than the heated support plate 150. Accordingly, this can increase process efficiency in the substrate W while minimizing the influence on nearby devices.

Furthermore, when the supercritical process is a supercritical deposition process, the process fluid includes a precursor (e.g., a metal precursor) of a deposition material. When the temperature of the substrate W is high, the metal precursor reacts with a reducing fluid so that a material (metal layer) can be efficiently deposited on the substrate W. On the other hand, when the temperatures of the vessels 110 and 130 are high, a metal layer may also be formed on inner walls of the vessels 110 and 130 that form the treatment space 180. The metal layer formed on the inner walls of the vessels 110 and 130 may interfere with a process or may act as a source of fumes/particles. Therefore, in the substrate treatment apparatus according to the embodiment of the present disclosure, only the support plate 150 is heated to a high temperature, and the upper vessel 110 and the lower vessel 130 are maintained at a relatively low temperature.

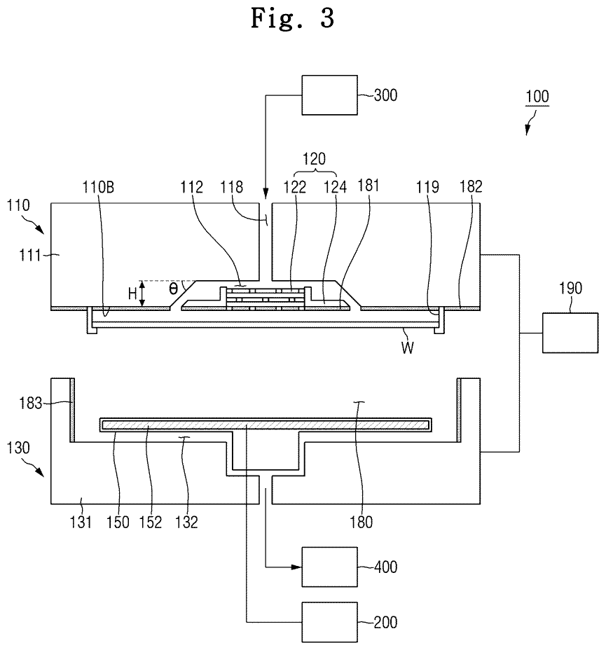

FIG. 3 illustrates a substrate treatment apparatus according to an embodiment of the present disclosure. For ease of description, the following description will focus on differences from the elements and features described with reference to FIGS. 1 and 2.

Referring to FIG. 3, in the substrate treatment apparatus according to the embodiment of the present disclosure, liners 181 through 183 made of a heat insulating material (i.e., a non-conductive heat insulating material) are disposed on parts exposed to a treatment space 180. The parts exposed to the treatment space 180 may be, for example, a baffle plate 120, an upper vessel 110, and a lower vessel 130. The liners 181 through 183 cool and insulate a peripheral area of the treatment space 180. The liners 181 through 183 may be, for example, polytetrafluoroethylene (PTFE) or ceramic, but the present disclosure is not limited thereto.

A first liner 181 is installed on a first portion of the baffle plate 120 which is exposed to the treatment space 180. For example, the first liner 181 may be installed on a lower surface of the baffle plate 120.

A second liner 182 is installed on a second portion of the upper vessel 110 which is exposed to the treatment space 180. Specifically, the upper vessel 110 may be divided into a center region CR (see FIG. 1) and a peripheral region PR (see FIG. 1), and the second liner 182 may be installed on a lower surface of the peripheral region PR.

A third liner 183 is installed on a third portion of the lower vessel 130 which is exposed to the treatment space 180. A second accommodating space 132 of the lower vessel 130 surrounds side and bottom surfaces of a support plate 150. The third liner 183 is installed on sidewalls of the second accommodating space 132.

Since the liners 181 through 183 made of a heat insulating material are installed on the parts exposed to the treatment space 180, even if the support plate 150 is heated to a high temperature, the heat does not affect the vessels 110 and 130 and peripheral devices of the vessels 110 and 130.

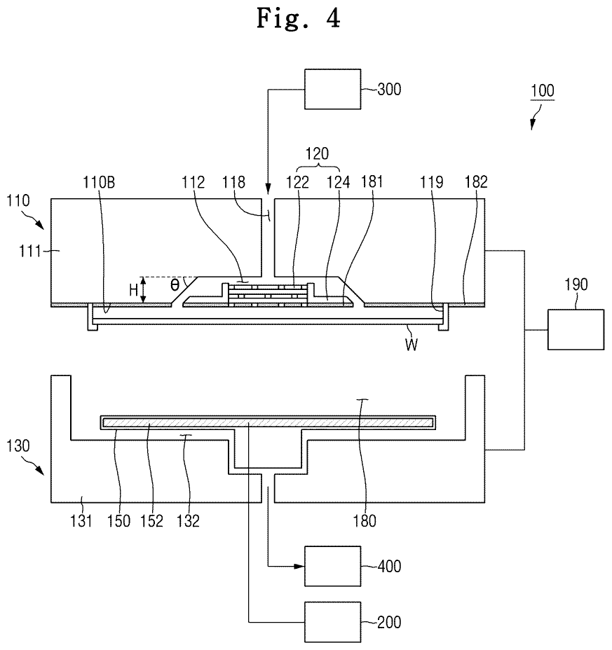

FIG. 4 illustrates a substrate treatment apparatus according to an embodiment of the present disclosure. For ease of description, the following description will focus on differences from the elements and features described with reference to FIGS. 1 through 3.

Referring to FIG. 4, in the substrate treatment apparatus according to the embodiment of the present disclosure, liners 181 and 182 made of a heat insulating material are installed on parts exposed to a treatment space 180. The liners 181 and 182 may be installed on a baffle plate 120 and an upper vessel 110 and may not be installed on a lower vessel 130.

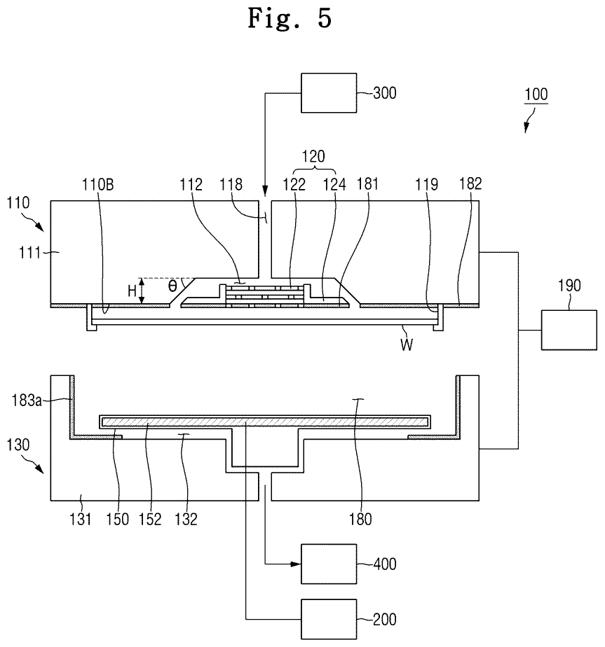

FIG. 5 illustrates a substrate treatment apparatus according to an embodiment of the present disclosure. For ease of description, the following description will focus on differences from the elements and features described with reference to FIGS. 1 through 3.

Referring to FIG. 5, in the substrate treatment apparatus according to the embodiment of the present disclosure, liners 181, 182 and 183a made of a heat insulating material are installed on parts exposed to a treatment space 180. The liners 181 and 182 are installed on a baffle plate 120 and an upper vessel 110. The liner 183a is installed on sidewalls and a bottom surface of a second accommodating space 132 of a lower vessel 130. Since the liner 183a is also installed on at least a portion of the bottom surface, it is possible to prevent heat from escaping toward the bottom surface and possible to prevent a material (metal layer) from being deposited on the bottom surface.

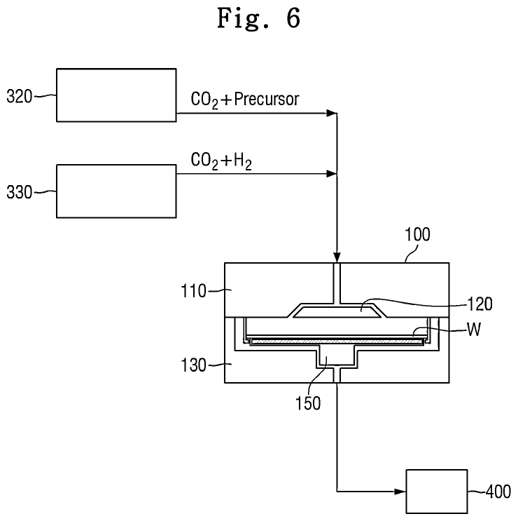

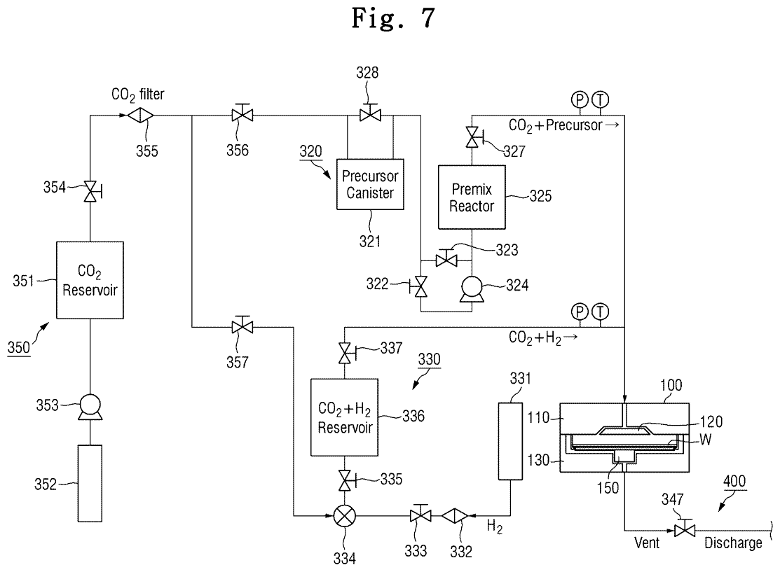

FIG. 6 is a diagram for explaining a process fluid supply unit of a substrate treatment apparatus according to embodiments of the present disclosure. FIG. 7 is an embodiment of FIG. 6.

First, referring to FIG. 6, the substrate treatment apparatus according to the embodiments of the present disclosure includes a reactor 100, a first process fluid supply unit 320, a second process fluid supply unit 330, and an exhaust unit 400. The first process fluid supply unit 320 and the second process fluid supply unit 330 correspond to the process fluid supply unit 300 of FIG. 1.

The first process fluid supply unit 320 supplies a first process fluid including a precursor and a first supercritical fluid into the reactor 100. That is, the first process fluid may include the precursor dissolved by the first supercritical fluid. The precursor may be, but is not limited to, a metal precursor. The metal precursor may be in the form of ML (where M is a metal, and L is a ligand), and the metal M may include Ru, Mo, Cu, TiN, TaN, Al, Ti, Ta, Ni, Nb, Rh, Pd, Ir, Ag, Au, Zn, or V, but the present disclosure is not limited thereto. The ligand L may consist of only C and/or H. However, the present disclosure is not limited thereto. That is, the ligand L may also consist of only one of Cₓ, H_{y}, and CₓH_{y} (where x and y are natural numbers).

The first process fluid may or may not maintain a supercritical state while being supplied to the reactor 100 (i.e., in a supply pipe connected to the reactor 100).

The first process fluid supply unit 320 may cause the internal pressure of the reactor 100 to rise above a critical pressure by supplying the first process fluid into the reactor 100. That is, the first process fluid may be in a supercritical state inside the reactor 100.

The second process fluid supply unit 330 supplies a second process fluid including a reducing fluid into the reactor 100. Examples of the reducing fluid include, but are not limited to, oxygen (O₂), hydrogen (H₂), and ammonia (NH₃). Optionally, the second process fluid may include a reducing fluid and a second supercritical fluid. That is, the second process fluid may include the reducing fluid dissolved by the second supercritical fluid.

The second process fluid may or may not maintain a supercritical state while being supplied to the reactor 100 (i.e., in a supply pipe connected to the reactor 100).

The second process fluid supply unit 330 may cause the internal pressure of the reactor 100 to rise above the critical pressure by supplying the second process fluid into the reactor 100. That is, the second process fluid may be in a supercritical state inside the reactor 100.

The exhaust unit 400 exhausts the fluid inside the reactor 100 to the outside.

Here, referring to FIG. 7, the first process fluid supply unit 320 and the second process fluid supply unit 330 receive a supercritical fluid (e.g., CO₂) from a supercritical fluid supply unit 350.

The supercritical fluid supply unit 350 includes a first cylinder 352, a syringe pump 353, a first reservoir 351, a filter 355, and valves 354, 356 and 357.

The first cylinder 352 stores liquefied carbon dioxide (LCO₂). For example, the first cylinder 352 may be controlled to about 40 bars and about 10° C., but the present disclosure is not limited thereto. The liquefied carbon dioxide is delivered to the first reservoir 351 through the syringe pump 353. The first reservoir 351 stores the carbon dioxide. In the first reservoir 351, the carbon dioxide may be in a supercritical state. For example, the first reservoir 351 may be controlled to about 180 bars and about 60° C., but the present disclosure is not limited thereto. That is, the first reservoir 351 may be controlled to a critical pressure of carbon dioxide (7.38 Mpa=73.8 bars) and a critical temperature (304.1K=30.95° C.) or higher.

The carbon dioxide in a supercritical state is supplied to the first process fluid supply unit 320 via the filter 355 and the valve 356. The first process fluid supply unit 320 includes a precursor canister 321, valves 322, 323, 324, 327 and 328, and a premix reactor 325.

The carbon dioxide provided from the supercritical fluid supply unit 350 is supplied to the precursor canister 321. In the precursor canister 321, a precursor is extracted by the carbon dioxide and provided to the premix reactor 325. The extracted precursor, together with the carbon dioxide, may be delivered to the premix reactor 325 through only the valve 323 or may be delivered to the premix reactor 325 through the valve 322 and the syringe valve 324.

In addition, the carbon dioxide provided from the supercritical fluid supply unit 350 may be directly supplied to the premix reactor 325 through the valve 328 without passing through the precursor canister 321.

In the premix reactor 325, a first process fluid (i.e., CO₂+precursor) in which the precursor and the carbon dioxide are mixed in a predetermined ratio is generated. The predetermined ratio may be achieved by using the carbon dioxide supplied without passing through the precursor canister 321. In addition, the premix reactor 325 may be controlled to about 170 bars and about 60 to 120° C., but the present disclosure is not limited thereto.

Whether to supply the first process fluid (i.e., CO₂+precursor) generated in the premix reactor 325 to the reactor 100 is determined according to whether the valve 327 is turned on or off.

Meanwhile, the carbon dioxide in a supercritical state is supplied to the second process fluid supply unit 330 via the filter 355 and the valve 357. The second process fluid supply unit 330 includes a second cylinder 331, a mixing unit 334, a second reservoir 336, a filter 332, and valves 333, 335 and 337.

The second cylinder 331 stores a reducing fluid, for example, hydrogen (H₂). The hydrogen is provided to the mixing unit 334 via the filter 332 and the valve 333.

The carbon dioxide provided from the supercritical fluid supply unit 350 and the hydrogen provided from the second cylinder 331 are mixed in the mixing unit 334 to generate a second process fluid (i.e., CO₂+H₂).

In the second reservoir 336, the second process fluid is stored. The second process fluid may be in a supercritical state in the second reservoir 336. The second reservoir 336 may be controlled to about 180 bars and about 60° C., but the present disclosure is not limited thereto.

Whether to supply the second process fluid (CO₂+H₂) stored in the second reservoir 336 to the reactor 100 is determined according to whether the valve 337 is turned on or off.

The exhaust unit 400 exhausts the fluid inside the reactor 100 to the outside. When a third valve 347 is turned on, an exhaust operation is performed. When the third valve 347 is turned off, the exhaust operation is stopped.

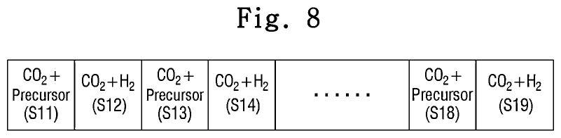

FIG. 8 is a diagram for explaining the operation of a substrate treatment apparatus according to embodiments of the present disclosure.

Referring to FIG. 8, the operation of the substrate treatment apparatus according to the embodiments of the present disclosure includes a plurality of cycles. The number of cycles may vary according to the thickness of a layer (e.g., a metal layer) to be deposited.

Each cycle repeats substantially the same operations.

Each cycle includes a first process fluid supply operation (S11, S13, . . . S18) and a second process fluid supply operation (S12, S14, . . . S19). A first cycle includes S11 and S12, a second cycle includes S13 and S14, and a last cycle includes S18 and S19.

In the first cycle S11 and S12, for example, in the first process fluid supply operation S11, a first process fluid including a precursor and a supercritical fluid is supplied to a reactor 100 so that the pressure of the reactor 100 repeatedly rises and falls a plurality of times within a first pressure range. The first pressure range is above a critical pressure. Then, the reactor 100 is vented to lower the pressure of the reactor 100 below the first pressure range.

In the second process fluid supply operation S12, a second process fluid including a reducing fluid is supplied to the reactor 100 so that the pressure of the reactor 100 repeatedly rises and falls a plurality of times within a second pressure range different from the first pressure range. A metal precursor and the reducing fluid react with each other. Then, the reactor 100 is vented to lower the pressure of the reactor 100 below the second pressure range.

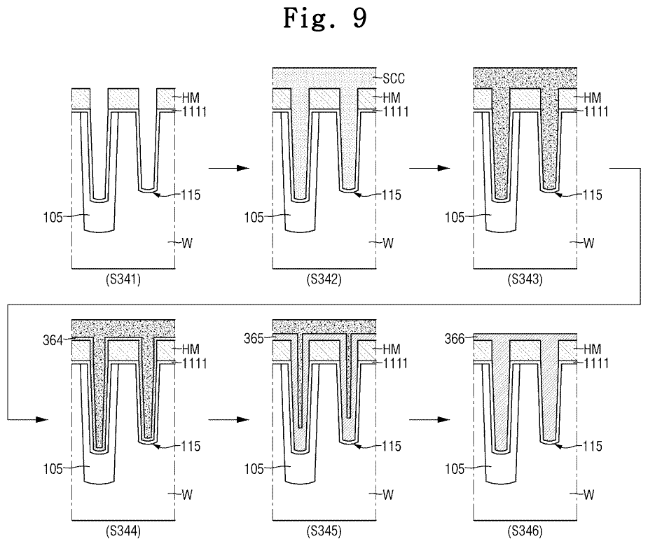

FIG. 9 is a diagram for explaining a process of filling a trench with a metal using a substrate treatment method according to embodiments of the present disclosure. For example, FIG. 9 illustrates a process of forming a word line (metal layer) in a word line trench in a DRAM.

Referring to FIG. 9, a substrate W having trenches 115 is placed in a reactor 100 (operation S341). Specifically, an element isolation layer 105 is formed in the substrate W, and a plurality of trenches 115 are formed. An insulating layer 1111 is conformally formed along inner walls of the trenches 115. In addition, a hard mask HM is formed.

Then, in the reactor 100, a metal precursor SCC in a supercritical state permeates into the trenches 115 (operation S342). Here, the permeating metal precursor SCC in the supercritical state corresponds to the first process fluid (i.e., CO₂+precursor) described above.

The metal precursor in the supercritical state has high permeability, very low surface tension, and high diffusivity compared with a liquid. In addition, the metal precursor in the supercritical state has high density and high solubility compared with a gas. Due to these characteristics, deposition of the metal precursor in the supercritical state may be faster than atomic layer deposition (ALD). In addition, step coverage is better than that of chemical vapor deposition (CVD), and the risk of defects/contamination can be minimized.

As described above, the flow of the first process fluid may be made in the reactor 100 by increasing and decreasing the pressure of the reactor 100 within a first pressure range by adjusting the supply of the first process fluid. Accordingly, the first process fluid more easily permeates into the trenches 115.

Next, a reducing fluid is provided into the reactor 100 (operation S343). Here, the provided reducing fluid corresponds to the second process fluid (CO₂+H₂) described above.

As described above, the flow of the second process fluid may be made in the reactor 100 by increasing and decreasing the pressure of the reactor 100 within a second pressure range by adjusting the supply of the second process fluid. Accordingly, the second process fluid more easily permeates into the trenches 115.

Next, the metal precursor and the reducing fluid react with each other to form a thin metal 364 in the trenches 115 (operation S344).

Next, as described above, as the supply of the metal precursor and the supply of the reducing fluid are repeated a plurality of times, a thickness of the metal 365 increases (operation S345).

Next, the metal 366 completely fills the trenches 115. The metal 366 may also be formed on upper surfaces of the trenches 115 (operation S346). The metal 366 formed here is referred to as a pre-metal layer.

Although not illustrated separately, a metal layer (i.e., a word line) filling a portion of each trench 115 is completed by removing a portion of the pre-metal layer 366 using atomic layer etching (ALE). A capping layer (a capping conductive layer and/or a capping insulating layer) may be additionally formed on the metal layer in each trench 115.

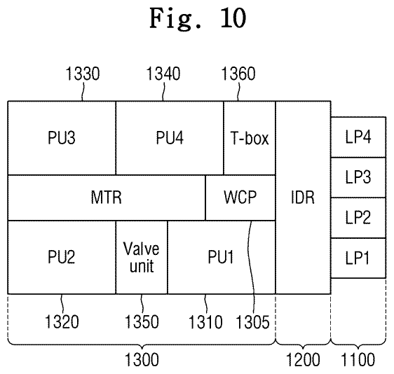

FIG. 10 illustrates a system to which a substrate treatment apparatus according to embodiments of the present disclosure is applied.

Referring to FIG. 10, the system includes a load port 1100, an index module 1200, and a process module 1300.

The load port 1100 includes a mounting table on which a container containing a plurality of substrates are placed (see LP1 through LP4). The container may be, for example, a front opening unified pod (FOUP), but the present disclosure is not limited thereto.

The index module 1200 (IDR) is disposed between the load port 1100 and the process module 1300. For example, the index module 1200 includes a rail installed in an index chamber and an index robot moving along the rail. The index robot includes an arm and a hand. The index robot picks up a substrate located in the load port 1100 and transfers the substrate to a buffer chamber 1305 (WCP).

The process module 1300 includes the buffer chamber 1305, a transfer chamber MTR, a first process chamber 1310 (PU1), a second process chamber 1320 (PU2), a third process chamber 1330 (PU3), a fourth process chamber 1340 (PU4), a valve unit 1350, and an electrical box 1360 (T-box).

The buffer chamber 1305 temporarily stores a substrate delivered by the index robot of the index module 1200. In addition, the buffer chamber 1305 may temporarily store a substrate which has gone through a preset process in at least one of the process chambers 1310, 1320, 1330 and 1340.

A guide rail and a transfer robot moving along the guide rail are installed in the transfer chamber MTR.

The first process chamber 1310, the valve unit 1350, and the second process chamber 1320 may be sequentially arranged on one side of the transfer chamber MTR. In addition, the electrical box 1360, the fourth process chamber 1340, and the third process chamber 1330 may be sequentially disposed on the other side of the transfer chamber MTR. That is, the transfer chamber MTR crosses between the first process chamber 1310 and the fourth process chamber 1340 and between the second process chamber 1320 and the third process chamber 1330.

At least one of the first process chamber 1310 through the fourth process chamber 1340 may correspond to the reactor 100 of the substrate treatment apparatus according to the embodiments of the present disclosure described above.

The valve unit 1350 is a space in which pipes and valves are installed to supply a chemical liquid (e.g., at least one of a precursor, a reducing fluid, a developing fluid, a cleaning fluid, and a rinsing fluid) and/or a supercritical fluid (e.g., carbon dioxide) to at least one of the process chambers 1310, 1320, 1330 and 1340.

The electrical box 1360 may be a space in which a plurality of electrical devices are installed. For example, an electrical device related to the fourth process chamber 1340 disposed adjacent to the electrical box 1360 may be installed in the electrical box 1360, but the present disclosure is not limited thereto.

While the present disclosure has been particularly illustrated and described with reference to exemplary embodiments thereof, it will be understood by those of ordinary skill in the art that various changes in form and detail may be made therein without departing from the spirit and scope of the present disclosure as defined by the following claims. The exemplary embodiments should be considered in a descriptive sense only and not for purposes of limitation.

What is claimed is:

1. A substrate treatment apparatus comprising:
an upper vessel comprising a first body and a supply port formed in the first body and supplying a process fluid;
a baffle plate installed in the upper vessel and supplying the process fluid supplied through the supply port to a treatment space by diffusing the process fluid;
a lower vessel comprising a second body and an exhaust port formed in the second body and exhausting the process fluid from the treatment space; and
a support plate installed in the lower vessel to face the baffle plate and supporting a substrate,
wherein while a supercritical process is performed in the treatment space, the support plate is heated so that the temperature of the support plate is higher than that of the first body.

2. The apparatus of claim 1, wherein the support plate is higher than the second body while the supercritical process is performed in the treatment space.

3. The apparatus of claim 1, wherein a heater is installed inside the support plate and operates while the supercritical process is performed.

4. The apparatus of claim 1, wherein a first liner made of a heat insulating material is installed on a first portion of the baffle plate which is exposed to the treatment space.

5. The apparatus of claim 1, wherein a second liner made of a heat insulating material is installed on a second portion of the upper vessel which is exposed to the treatment space.

6. The apparatus of claim 5, wherein the first body comprises a center region and a peripheral region surrounding the center region, a first accommodating space connected to the support port and having the baffle plate located therein is formed in the center region, the peripheral region protrudes from the center region, and the second liner is installed in the peripheral region.

7. The apparatus of claim 1, wherein a third liner made of a heat insulating material is installed on a third portion of the lower vessel which is exposed to the treatment space.

8. The apparatus of claim 7, wherein a second accommodating space connected to the exhaust port and having the support plate located therein is formed in the second body, and the third liner is installed on sidewalls of the second accommodating space.

9. The apparatus of claim 1, wherein a liner is installed on at least one of the baffle plate, the upper vessel and the lower vessel which form the treatment space, and the liner comprises polytetrafluoroethylene (PTFE) or ceramic.

10. The apparatus of claim 9, wherein the upper vessel and the lower vessel comprise stainless steel (SUS).

11. The apparatus of claim 1, further comprising a support installed on the first body and supporting edges of the substrate, wherein the substrate is placed on the support in a state where the upper vessel and the lower vessel are spaced apart from each other and is transferred from the support to an upper surface of the support plate in a state where the upper vessel and the lower vessel are in contact with each other.

12. The apparatus of claim 1, wherein while the supercritical process is performed in the treatment space, the first body is controlled to 35 to below 150° C., and the support plate is controlled to 150 to 350° C.

13. The apparatus of claim 1, wherein the process fluid is a first process fluid comprising a metal precursor and a supercritical fluid or a second process fluid comprising a reducing fluid.

14. The apparatus of claim 13, supplying the first process fluid to the treatment space so that the first process fluid is in a supercritical state in the treatment space, venting the treatment space, supplying the second process fluid to the treatment space so that the metal precursor and the reducing fluid react with each other, and then venting the treatment space again.

15. A substrate treatment apparatus comprising:
vessels providing a treatment space for treating a substrate and comprising an upper vessel and a lower vessel detachably coupled so that the upper vessel and the lower vessel can be switched between a closed position for closing the treatment space and an open position for opening the treatment space;
a support installed on a lower surface of the upper vessel and configured to support the substrate in the open position of the vessels;
a hot plate installed in the lower vessel and heating a lower surface of the substrate in the closed position of the vessels; and
a liner installed on at least a portion of an inner wall of the treatment space and made of a heat insulating material.

16. The apparatus of claim 15, wherein while a supercritical process is performed in the treatment space, the temperature of the hot plate is controlled to be higher than those of the vessels.

17. The apparatus of claim 16, wherein while the supercritical process is performed in the treatment space, the vessels are controlled to 35 to below 150° C., and the hot plate is controlled to 150 to 350° C.

18. The apparatus of claim 15, wherein the vessels comprise SUS, and the liner comprises PTFE or ceramic.

19. The apparatus of claim 15, wherein in the closed position of the vessels, the hot plate receives the substrate from the support and supports the received substrate.

20. A substrate treatment apparatus comprising:
an upper vessel which comprises a first body comprising a center region and a peripheral region, a supply port formed in the center region and supplying a process fluid, and a first accommodating space connected to the supply port in the center region and recessed inward from the peripheral region;
a baffle plate installed in the first accommodating space and supplying the process fluid supplied through the supply port to a treatment space by diffusing the process fluid;
a lower vessel comprising a second body, an exhaust port formed in the second body and exhausting the process fluid from the treatment space, and a recessed second accommodating space;
a hot plate installed in the second accommodating space to face the baffle plate;
a first heat insulating liner installed on a lower surface of the baffle plate;
a second heat insulating liner installed on a lower surface of the peripheral region of the first body; and
a third heat insulating liner installed on sidewalls of the second accommodating space which surround side surfaces of the hot plate,
wherein while a supercritical process is performed in the treatment space, the hot plate is heated so that the temperature of the hot plate is higher than those of the first body and the second body.
